(19) United States
(12) Patent Application Publication
(10) Pub. No.: US 2009/0082075 A1
(43) Pub. Date: Mar. 26, 2009

(54) CASING AND METHOD FOR MANUFACTURING SAME, AND ELECTRONIC DEVICE

(76) Inventors: Tomoko Honda, Kanagawa-ken (JP); Fujio Takahashi, Kanagawa-ken (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 12/211,273

(22) Filed: Sep. 16, 2008

(30) Foreign Application Priority Data
Sep. 25, 2007 (JP) 2007-248196

(51) Int. Cl. H04M 1/00; H05K 7/00; B05D 5/12

(52) U.S. Cl. 455/575.7; 361/679.01; 427/58

(57) ABSTRACT

A casing includes a molded body provided with a recess, a conductive layer provided in the recess, and a protection film provided to cover at least a non-recessed region in a surface of the molded body provided with the recess and a surface of the conductive layer. The protection film extends generally evenly over the non-recessed region and the surface of the conductive layer. A method manufacturing the same and an electronic device including the casing are provided.

### CROSS-REFERENCE TO RELATED APPLICATIONS

This application is based upon and claims the benefit of priority from the prior Japanese Patent Application No. 2007-248196, filed on Sep. 25, 2007; the entire contents of which are incorporated herein by reference.

### BACKGROUND OF THE INVENTION

1. Field of the Invention

This invention relates to a casing and a method for manufacturing the same, and an electronic device.

2. Background Art

With an increasing demand for downsizing electronic devices such as mobile phones and notebook personal computers, it is necessary to enhance the flexibility of antenna design even in a small space.

In this case, for example, inside the casing of a mobile phone, if a built-in antenna based on sheet metal, in-mold decoration, or MID (molded interconnect device) is placed between the circuit board and the casing, the implementation space is increased. Furthermore, ribs and bosses, often placed inside the casing, constrains the layout and shape of the antenna.

On the other hand, if the antenna is placed on the outer surface of the casing, the implementation space is easily ensured, but the antenna thickness is likely to produce a step difference, which impairs the appearance of the design.

JP 2003-158415A discloses a technique related to wireless communication devices, which proposes a small, lightweight terminal device for mobile communication with enhanced flexibility in appearance design. In this technique, the outer surface and outer periphery of the casing of a dielectric resin antenna is covered with a low-dielectric resin, and the remaining portion of the casing is made of a conductive resin. However, the space for housing the antenna is insufficient.

### SUMMARY OF THE INVENTION

According to an aspect of the invention, there is provided a casing including: a molded body provided with a recess; a conductive layer provided in the recess; and a protection film provided to cover at least a non-recessed region in a surface of the molded body provided with the recess and a surface of the conductive layer, the protection film extending generally evenly over the non-recessed region and the surface of the conductive layer.

According to an aspect of the invention, there is provided a method for manufacturing a casing, including: forming a conductive layer in a recess provided in a surface of a molded body, the conductive layer having a thickness generally equal to the depth of the recess; and forming a protection film to generally evenly cover a non-recessed region in the surface of the molded body provided with the recess and a surface of the conductive layer.

According to an aspect of the invention, there is provided an electronic device including: a first casing; a second casing combined with the first casing; and an electrical circuit provided in an internal space formed between the first casing and the second casing, at least one of the first casing and the second casing including: a molded body provided with a recess; a conductive layer provided in the recess; and a protection film provided to cover at least a non-recessed region in a surface of the molded body provided with the recess and a surface of the conductive layer, the protection film extending generally evenly over the non-recessed region and the surface of the conductive layer, the first and second casing being combined so that the protection film is located on the outer surface side, and the conductive layer being electrically connected to the electrical circuit.

### BRIEF DESCRIPTION OF THE DRAWINGS

FIGS. 1A and 1B are schematic views of an electronic device according to this embodiment;

FIGS. 2A and 2B are schematic cross-sectional views of a display unit;

FIG. 3 is a schematic cross-sectional view near a conductive layer;

FIGS. 4A to 4D are process cross-sectional views illustrating a method for manufacturing the casing of this embodiment;

FIG. 5 is a flow chart showing the method for manufacturing the casing;

FIG. 6 is a schematic cross-sectional view showing a casing according to a comparative example;

FIGS. 7A to 7C are process cross-sectional views illustrating a variation of the method for manufacturing the casing; and

FIGS. 8A and 8B are schematic views showing a variation of electrical connection to the conductive layer.

### DETAILED DESCRIPTION OF THE INVENTION

An embodiment of the invention will now be described with reference to the drawings.

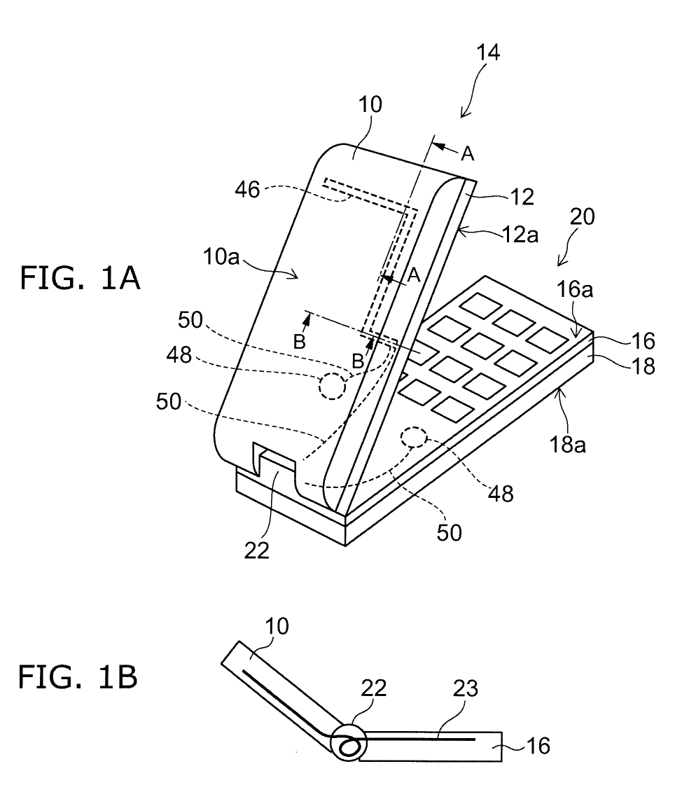

FIG. 1 shows an electronic device according to the embodiment of the invention, in which FIG. 1A is a schematic perspective view, and FIG. 1B is a schematic cross-sectional view showing an example of electrical connection based on a flexible circuit board. A first casing 10 including a molded body is combined with a second casing 12 including a molded body. In a mobile device such as a mobile phone, the first and second casing 10, 12 are combined to constitute a display unit 14. On the other hand, a third casing 16 and a fourth casing 18 are combined to constitute an operation unit 20.

FIG. 1A shows a folding mobile phone in which the display unit 14 is mechanically and electrically linked to the operation unit 20 by a hinge 22. Possible types of combining the units also include the sliding type and the rotary type, but the invention is not limited to these combining types. FIG. 1B shows a cross section in which the display unit 14 is electrically connected to the operation unit 20 by a flexible circuit board 23 passing through the gap in the hinge 22.

The surface 10a of the first casing 10 is provided with a protection film, and a conductive layer 46 is provided therebelow. Above the end of the conductive layer 46, the surface 10a extends generally evenly and is continuously formed without step difference. Hence, the presence of the conductive layer 46 is not noticeable in appearance. This surface 10a is referred to as the design surface. That is, this embodiment can prevent the step difference of the conductive layer 46 from affecting the design surface and keep a good appearance. It is noted that the gradually rounded and continuous configuration of the first casing 10 as in FIG. 1A is also herein referred to as being “generally even”. Furthermore, alternatively, the conductive layer 46 can be provided on the surface 12a side of the second casing 12. That is, in the opened state of the mobile phone, the surface 10a and the side face of the first casing 10 and the surface 12a and the side face of the second casing 12 constitute the design surface.

The conductive layer 46 can illustratively serve as an antenna. The antenna may be provided on any of the surfaces 10a, 12a, 16a, 18a of the first, second, third, and fourth casing 10, 12, 16, 18. This embodiment, which can ensure a large antenna housing space and make effective use of the casing surface, is desirable in providing a plurality of antennas in the mobile phone. Furthermore, placing the antenna on the design surface side facilitates reducing noise from the circuit board 30.

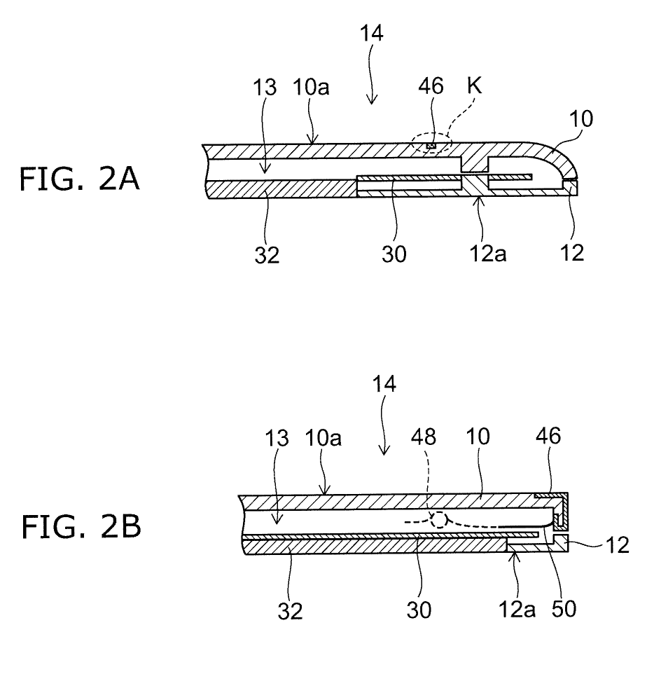

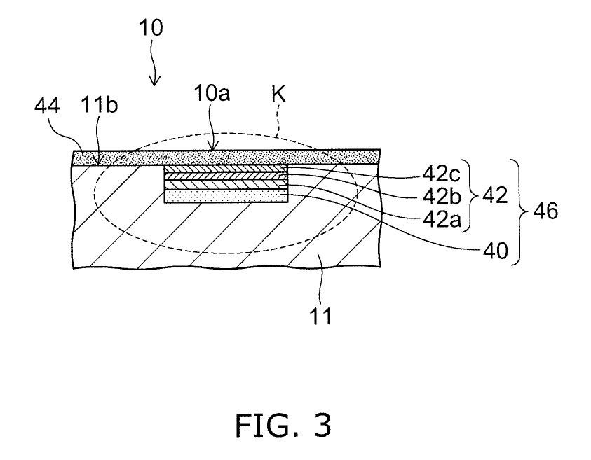

FIG. 2 is a schematic cross-sectional view of the display unit 14, in which FIG. 2A shows a cross section taken along line A-A of FIG. 1, and FIG. 2B shows a cross section taken along line B-B. While the display unit 14 is described herein, this embodiment is not limited thereto, but is also applicable to the operation unit 20. FIG. 3 is a schematic view partly enlarging the portion K of FIG. 2A. In FIG. 2A, the first and second casing 10, 12 are combined to form an internal space 13. A liquid crystal display 32, for example, is fixed to the second casing 12. Furthermore, a circuit board 30 illustratively provided with an electrical circuit is fixed to either the first casing 10 or the second casing 12.

In the case where the electronic device is composed of the display unit 14 and the operation unit 20 as in FIG. 1, an electrical circuit is often also placed in the operation unit 20. In the case where the conductive layer 46 is an antenna, it is electrically coupled to and fed by a high-frequency unit 48. The high-frequency unit 48 includes an oscillator and a receiver and can be placed in either the display unit 14 or the operation unit 20. As in FIG. 2B, the feed line 50 of the electrical circuit is connected to the conductive layer 46 of the first casing 10. Here, in the case where the molded body is made of resin, a connection pin penetrating the first casing 10 can be used as part of the feed line to feed the conductive layer 46. It is noted that the display unit 14 is electrically connected to the operation unit 20 through the hinge 22.

FIG. 3 is a schematic cross-sectional view near the conductive layer 46. The conductive layer 46 is provided in a recess of the molded body 11. For example, a plating layer 42 is formed on a conductive paste layer 40. The thickness of the conductive layer 46 composed of the conductive paste layer 40 and the plating layer 42 is generally equal to the depth of the recess. A protection film 44 such as a coating film is provided to cover the surface of the portion of the molded body 11 located outside the recess, that is, the non-recessed region 11b, and the surface of the plating layer 42. There is no step difference between the surface of the conductive layer 46 and the surface of the molded body 11. Thus, no step difference occurs at the surface of the protection film 44, which facilitates making a good design surface. That is, the protection film 44 extends generally evenly over the conductive layer 46 and the molded body 11, forming a continuous surface.

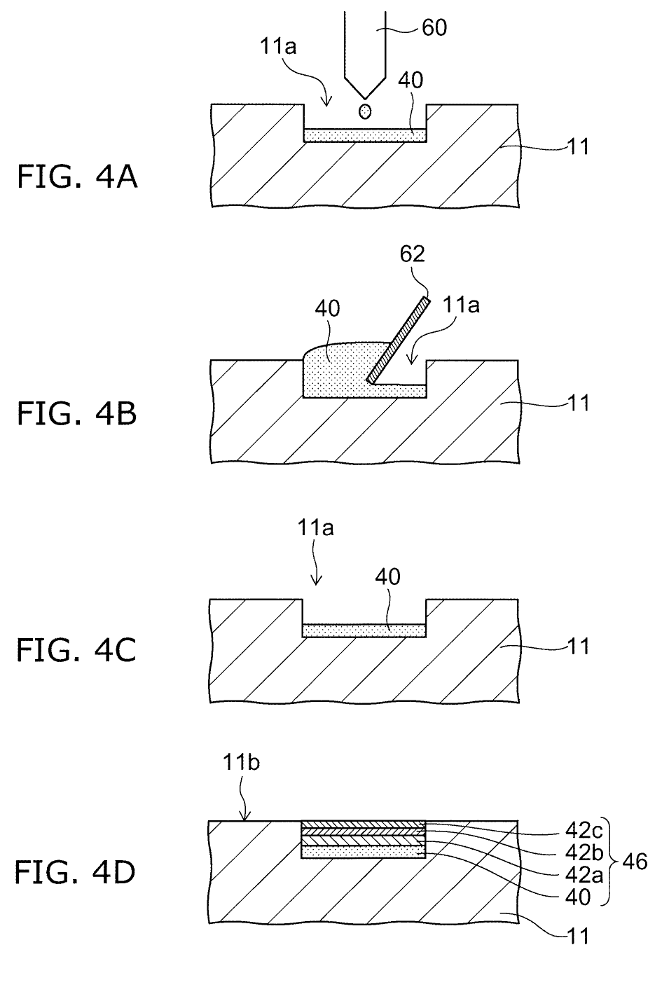

FIG. 4 is a process cross-sectional view illustrating a method for manufacturing the casing of this embodiment.

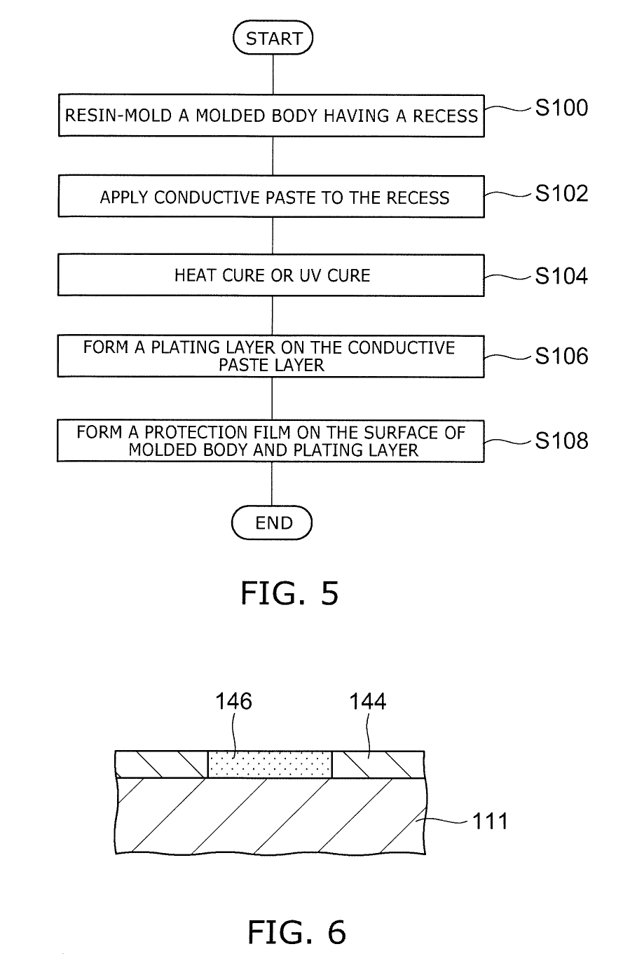

FIG. 5 is a flow chart showing the method for manufacturing the casing.

First, a molded body 11 having a recess 11a is resin-molded (S100). The resin material can be PC (polycarbonate), ABS (acrylonitrile butadiene styrene), PET (polyethylene terephthalate), PC/ABS, PPS (polyphenylene sulfide), PPO (polyphenylene oxide), PI (polyimide), POM (polyoxymethylene), PES (polyethersulfone), RENY, PP (polypropylene), PMMA (polymethyl methacrylate), PS (polystyrene), AS (acrylonitrile styrene), PPE (polyphenyl ether), PEEK, LCP, COC, and COP. As in FIG. 4A, conductive paste is dropped into the recess 11a from a dot dispenser 60, for example. The conductive paste can be a dispersion of silver (Ag) particles in a solvent. Here, as in FIG. 4B, the conductive paste can be dropped thicker than the depth of the recess 11a and flattened with a blade 62 to be thinner than the depth of the recess 11a. If the blade 62 is made of rubber or other elastic material, the conductive paste can be easily shaped in accordance with the curvature of the casing (S102). The thickness of the conductive paste layer 40 is illustratively 5 to 30 μm.

Subsequently, as in FIG. 4C, the conductive paste layer 40 is cured illustratively by heat treatment at approximately 100° C. for 10 to 30 minutes, or by UV irradiation (S104). Furthermore, as in FIG. 4D, it is plated with, for example, copper (Cu) 42a (thickness 10 μm), nickel (Ni) 42b (thickness 2 μm), and gold (Au) 42c (thickness 0.3 μm) in this order (S106). Plating can be either electroplating or electroless plating. Cu decreases skin depth at high frequencies, Ni retains hardness, and Au serves for protection against oxidation and the like.

The skin depth at 1 GHz is approximately 2.1 μm for Cu, approximately 4.1 μm for Ni, and approximately 2.5 μm for Au. Cu has high conductivity and can decrease skin depth, allowing the conductive layer 46 to be thinned. Hence, it is desirable to include Cu in the plating layer 42. The total thickness of the conductive layer 46 consisting of the conductive paste layer 40 and the plating layer 42 is made generally equal to the depth of the recess 11a to eliminate step difference. Alternatively, the conductive layer 46 can be a thin sheet metal and illustratively stuck to the inside of the recess 11a.

There is no step difference between the molded body 11 and the conductive layer 46 provided in the recess 11a. A protection film 44 is formed to cover this even surface (S108). Thus, as in FIG. 3, an even surface 10a with no noticeable pattern of the conductive layer 46 is produced as a design surface. The protection film 44 can illustratively be a spray coating film (with a thickness of 1 to several ten μm). It is also possible to use pad printing, a resin film coated with a coating film, or an opaque film.

FIG. 6 is a schematic cross-sectional view of a casing according to a comparative example. A conductive layer 146 made of conductive paste or the like is formed on the surface of a molded body 111. The surface of the conductive layer 146 is coated with a paint-repellent material, and a coating film 144 is formed on the surface of the casing outside the conductive layer 146 up to a height generally equal to the height of the conductive layer 146. In this case, it is necessary to form a thick coating film 144 having a thickness generally equal to the thickness of the conductive layer 146, and further cover the top of the coating film 144 and the conductive layer 146. Thus, the manufacturing process is complicated. In contrast, this embodiment is simpler in the manufacturing method, and the protection film 44 such as the coating film can be thinned.

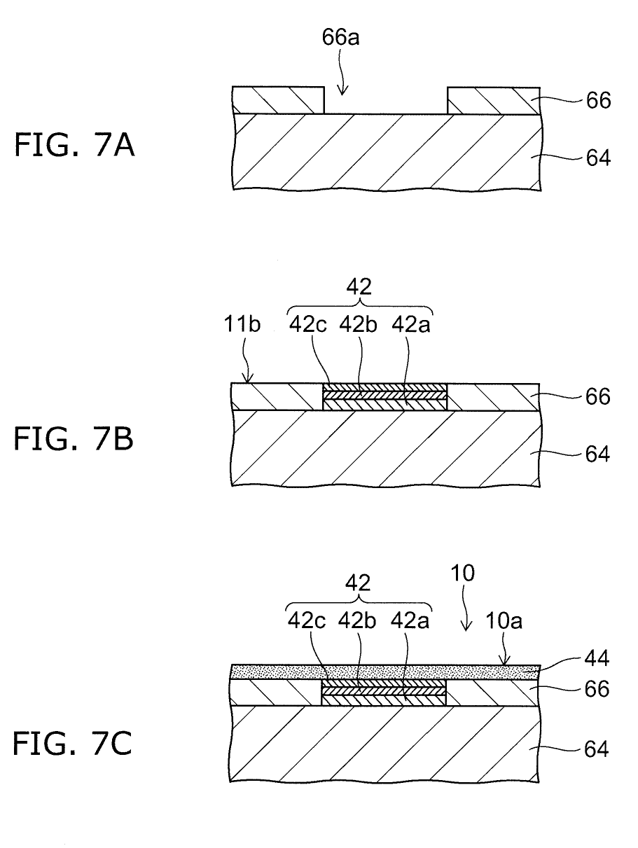

FIG. 7 is a process cross-sectional view illustrating a variation of the method for manufacturing the casing. As in FIG. 7A, a first molded body 64 is resin-molded, and a second molded body 66 having an opening 66a is resin-molded. The first molded body 64 is illustratively made of ABS (acrylonitrile butadiene styrene) resin, which has good adhesiveness to foundation paste containing palladium (Pd) or other catalyst. On the other hand, the second molded body 66 is illustratively made of polycarbonate resin, which has insufficient adhesiveness. Such a molding method based on two resins is referred to as two-color molding.

The first molded body 64, constituting the bottom of the recess 66a as in FIG. 7, has good adhesiveness to the foundation paste. Thus, Cu, Ni, Au and the like can be directly formed by plating inside the recess 66a. Here, the second molded body 66 has insufficient adhesiveness to the foundation paste, and no plating layer is formed thereon. Furthermore, as in FIG. 7C, there is no step difference between the second molded body 66 and the plating layer 42. Thus, a protection film 44 such as a coating film is evenly formed and can realize a design surface with good appearance, which covers over the plating layer 42 serving as an antenna or the like. In this variation, the conductive layer 46 can be thinned using a Cu plating layer, and the manufacturing method can be further simplified.

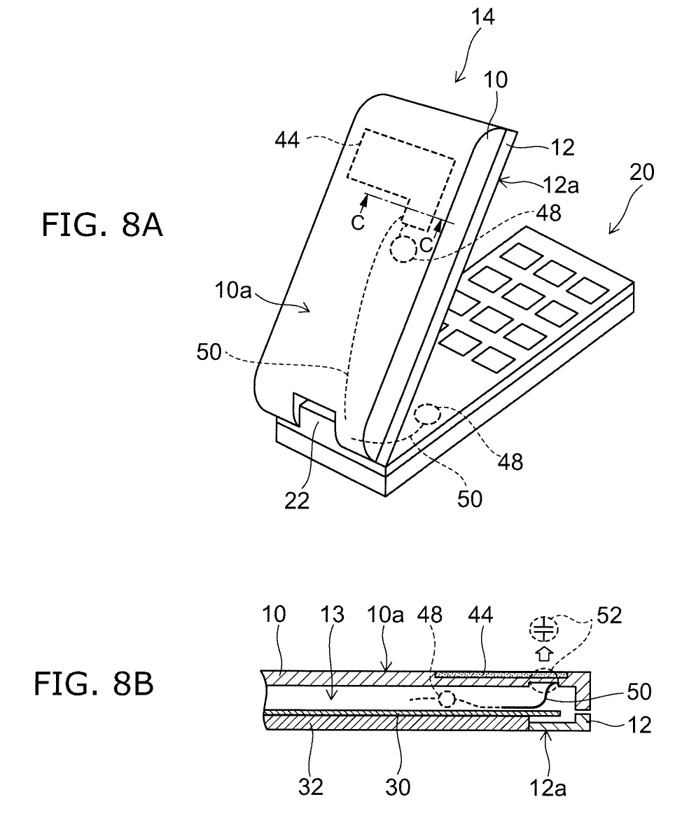

FIG. 8 is a schematic view showing a variation of electrical connection to the conductive layer, in which FIG. 8A is a schematic perspective view, and FIG. 8B is a schematic cross-sectional view taken along line C-C. For example, the antenna has a planar shape as in FIG. 8A. The antenna, implemented as a conductive layer 46 below the protection layer 44 of the surface 10a, is fed from the high-frequency unit 48 on the inner side of the first casing 10 by a capacitively coupled device such as a capacitor 52. The high-frequency unit 48 can be placed in either the display unit 14 or the operation unit 20. Thus, the antenna can be fed without a feed line penetrating the molded body.

As described above, this embodiment can realize a casing with improved appearance while retaining the space for housing the conductive layer by eliminating surface step difference between the conductive layer and the molded body and providing a protection film such as a coating film on the surface. In particular, in the case of using the conductive layer as an antenna, the antenna housing space can be more easily ensured than inside the casing, increasing the flexibility of antenna design. Thus, transmitting and receiving function can be extended to the triple band including GSM (Global System for Mobile communications), DCS (Digital Cellular System), and PCS (Personal Communications Service), as well as wireless LAN, FM broadcasting, AM broadcasting, GPS (global positioning system), and One Seg.

This embodiment has been described with reference to a folding electronic device having an opened and closed state in which a display unit is linked to an operation unit. However, the invention is not limited thereto, but the display unit can be integrated with the operation unit. Furthermore, the electronic device can be a mobile phone, a PDA (personal digital assistant), or a personal computer.

The embodiment of the invention has been described with reference to the drawings. However, the invention is not limited to this embodiment. The material, size, shape, and layout of the molded body, recess, conductive paste, plating layer, conductive layer, protection film, and coating film constituting the casing and the electronic device can be modified by those skilled in the art without departing from the spirit of the invention, and such modifications are also encompassed within the scope of the invention.

1. A casing comprising:
a molded body provided with a recess;
a conductive layer provided in the recess; and
a protection film provided to cover at least a non-recessed region in a surface of the molded body provided with the recess and a surface of the conductive layer,
the protection film extending generally evenly over the non-recessed region and the surface of the conductive layer.

2. The casing according to claim 1, wherein the conductive layer has a thickness generally equal to the depth of the recess.

3. The casing according to claim 1, wherein the conductive layer includes a conductive adhesive layer and a plating layer laminated in this order.

4. The casing according to claim 3, wherein the plating layer contains copper.

5. The casing according to claim 1, wherein the molded body includes:
a first molded body having a generally even surface; and
a second molded body formed on the first molded body and having a penetrating opening which constitutes the recess.

6. The casing according to claim 5, wherein the conductive layer includes a conductive adhesive layer and a plating layer laminated in this order.

7. The casing according to claim 5, wherein adhesion strength between the first molded body and a plating foundation paste is higher than adhesion strength between the second molded body and the plating foundation paste.

8. The casing according to claim 7, wherein the conductive layer is a plating layer formed on the surface of the first molded body.

9. The casing according to claim 8, wherein the plating layer contains copper.

10. The casing according to claim 7, wherein
the first molded body includes an ABS resin, and
the second molded body includes a polycarbonate resin.

11. The casing according to claim 1, wherein the protection film is a coating film.

12. A method for manufacturing a casing, comprising:
forming a conductive layer in a recess provided in a surface of a molded body, the conductive layer having a thickness generally equal to the depth of the recess; and
forming a protection film to generally evenly cover a non-recessed region in the surface of the molded body provided with the recess and a surface of the conductive layer.

13. The method for manufacturing a casing according to claim 12, wherein the protection film is any one of a spray coating film, a pad printing coating film, a resin film, and an opaque film.

14. The method for manufacturing a casing according to claim 12, wherein the conductive layer includes an adhesive layer formed by curing a conductive adhesive dropped into the recess.

15. The method for manufacturing a casing according to claim 12, wherein the conductive layer includes:
an adhesive layer formed by curing a conductive adhesive dropped into the recess; and
a plating layer laminated to a surface of the adhesive layer.

16. The method for manufacturing a casing according to claim 12, wherein
the molded body includes:
a first molded body having a generally even surface; and
a second molded body formed on the first molded body and having a penetrating opening which constitutes the recess, and
the conductive layer is a plating layer selectively formed on a surface of the first molded body exposed to the opening of the second molded body.

17. An electronic device comprising:
a first casing;
a second casing combined with the first casing; and
an electrical circuit provided in an internal space formed between the first casing and the second casing,
at least one of the first casing and the second casing including:
a molded body provided with a recess;
a conductive layer provided in the recess; and
a protection film provided to cover at least a non-recessed region in a surface of the molded body provided with the recess and a surface of the conductive layer,
the protection film extending generally evenly over the non-recessed region and the surface of the conductive layer,
the first and second casing being combined so that the protection film is located on the outer surface side, and
the conductive layer being electrically connected to the electrical circuit.

18. The electronic device according to claim 17, wherein the conductive layer includes an antenna.

19. The electronic device according to claim 18, wherein the antenna is fed through a feed line of the electrical circuit.

20. The electronic device according to claim 18, wherein the antenna is fed through a capacitively coupled device of the electrical circuit.
